(19) United States
(12) Patent Application Publication
(10) Pub. No.: US 2015/0083473 A1
(43) Pub. Date: Mar. 26, 2015

(54) FLEXIBLE ELECTRONIC FIBER-REINFORCED COMPOSITE MATERIALS

(71) Applicant: CUBIC TECH CORPORATION, MESA, AZ (US)

(72) Inventors: Roland Joseph Downs, Mesa, AZ (US); Heiner W. Meldner, Reno, NV (US); Christopher Michael Adams, Mesa, AZ (US)

(73) Assignee: CUBIC TECH CORPORATION, MESA, AZ (US)

(21) Appl. No.: 14/208,107

(22) Filed: Mar. 13, 2014

Related U.S. Application Data
(60) Provisional application No. 61/784,968, filed on Mar. 14, 2013.

(51) Int. Cl. H05K 1/03; H05K 1/09; H05K 3/00; H05K 3/06; H05K 3/12; H05K 3/02

(52) U.S. Cl. CPC H05K 1/0366; H05K 3/12; H05K 3/022; H05K 3/0014; H05K 3/0011; H05K 3/06; H05K 1/09; H05K 1/0373; H05K 1/0393
USPC 174/257; 428/298.1; 428/109; 428/110; 427/123; 156/60; 264/129; 264/132; 156/277; 156/280; 216/17

(57) ABSTRACT

Flexible electronic substrate systems relating to providing a system for dimensionally-stable substrate systems to support electronic systems is provided.

### CROSS REFERENCE TO RELATED APPLICATION

This application claims priority to U.S. Provisional Patent Application Ser. No. 61/784,968 filed Mar. 14, 2013, which is incorporated herein by reference in its entirety.

Related disclosures are found in U.S. Pat. No. 5,470,062, entitled “COMPOSITE MATERIAL FOR FABRICATION OF SAILS AND OTHER ARTICLES,” which was issued on Nov. 28, 1995; and U.S. Pat. No. 5,333,568, entitled “MATERIAL FOR THE FABRICATION OF SAILS” which was issued on Aug. 2, 1994; and U.S. patent application Ser. No. 13/168,912, filed Jun. 24, 2011 entitled “WATERPROOF BREATHABLE COMPOSITE MATERIALS FOR FABRICATION OF FLEXIBLE MEMBRANES AND OTHER ARTICLES,”; and U.S. patent application Ser. No. 13/197,741, filed Aug. 3, 2011 entitled “SYSTEM AND METHOD FOR THE TRANSFER OF COLOR AND OTHER PHYSICAL PROPERTIES TO LAMINATE COMPOSITE MATERIALS AND OTHER ARTICLES”, the contents of all of which are hereby incorporated by reference for any purpose in their entirety.

### BACKGROUND

This invention relates to providing improved monofilament-related products, methods, and equipment. More particularly, this invention relates to flexible electronic substrate systems.

In the past, there has been difficulty in achieving desired combinations of efficiently controlling properties of fabric-related products, including but not limited to: weight, rigidity, penetrability, waterproof-ability, breathability, color, mold-ability, cost, customizability, flexibility, package-ability, etc., including desired combinations of such properties, especially with regard to fabric-related products like clothing and shoes, camping and hiking goods, comfortable armor, protective inflatables, etc.

Electronics depend upon precise location and dimensional tolerance of elements and features such as circuits and traces, even to the micron level, and are trending to an even smaller scale. Current flexible electronic technology is based on low strength, low modulus, unreinforced plastic film. Such plastic films must be relatively thick to carry out proper function and have sufficient mechanical properties to provide a substrate with low stretch, Coefficient of Thermal Expansion (CTE), and moisture swelling properties, thus providing a substrate with sufficient dimensional stability to withstand fabrication processes and further providing in-service durability.

The resolution of printed electronic components on flexible substrates is currently limited by the properties of the substrate. This instability of currently-available substrates creates limitations in the accuracy and size of structures creatable. As such, there is a need for thin, flexible, low mass, large area substrates with high dimensional stability.

Additionally, there are several problems to be solved when using thin flexible substrates, such as, for example, substrates should preferably have a low heat transfer coefficient, ideally able to control the planar directionality of heat flow; thermal expansion and (non-thermal) shrinkage can create instability and damage to electronic circuits; moisture resistance may be critical to shield the electronic circuits from damage; a smooth surface with the ability to print or deposit electronically conductive material is preferably to create electronic structures.

### OBJECTS AND FEATURES OF THE INVENTION

A primary object and feature of the present invention is to provide a system overcoming the above-mentioned problem(s).

Another primary object and feature of the present invention is to provide a system to fine-tune, at desired places on a product, directional control of rigidity/flexibility/elasticity properties.

Yet another primary object and feature of the present invention is to provide products combining extreme light weight with extreme strength.

It is a further object and feature of the present invention to provide such a system providing continuous bulk manufacture of such products and their constituent parts.

Another object and feature of the present invention is to provide adaptability to the various stations of such continuous bulk manufacturing system.

A further primary object and feature of the present invention is to provide such a system that is efficient, inexpensive, and handy. Other objects and features of this invention will become apparent with reference to the following descriptions.

### SUMMARY OF THE INVENTION

In accordance with a preferred embodiment hereof, this invention provides a laminate including reinforcing elements therein, such reinforcing elements including at least one unidirectional tape having monofilaments therein, all of such monofilaments lying in a predetermined direction within the tape, wherein such monofilaments have diameters less than 20 microns and wherein spacing between individual monofilaments within an adjoining strengthening group of monofilaments is within a gap distance in the range between non-abutting monofilaments up to nine times the monofilament major diameter.

Moreover, it provides such a laminate wherein such monofilaments are extruded. Additionally, it provides such a laminate wherein such reinforcing elements include at least two unidirectional tapes, each having extruded monofilaments therein, all of such monofilaments lying in a predetermined direction within the tape, wherein such monofilaments have diameters less than 20 microns and wherein spacing between individual monofilaments within an adjoining strengthening group of monofilaments is within a gap distance in the range between non-abutting monofilaments up to nine times the monofilament major diameter. Also, it provides such a laminate wherein each of such at least two unidirectional tapes includes larger areas without monofilaments therein and wherein such larger areas comprise laminar overlays comprising smaller areas without monofilaments.

In addition, it provides such a laminate wherein such smaller areas comprise user-planned arrangements. And, it provides such a laminate further comprising a set of water-breathable elements comprising laminar overlays of such smaller areas. Further, it provides such a laminate further comprising a set of other laminar overlays. Moreover, it provides such a laminate wherein a first one of such at least two unidirectional tapes includes monofilaments lying in a different predetermined direction than a second one of such at least two unidirectional tapes.

Additionally, it provides such a laminate wherein a combination of the different predetermined directions of such at least two unidirectional tapes is user-selected to achieve laminate properties having planned directional rigidity/flexibility. Also, it provides such a laminate comprising a three-dimensionally shaped, flexible composite part. In addition, it provides such a product comprising multiple laminate segments attached along peripheral joints. And, it provides such a product comprising at least one laminate segment attached along peripheral joints with at least one non-laminate segment. Further, it provides such a product comprising multiple laminate segments attached along area joints.

Even further, it provides such a product comprising at least one laminate segment attached along area joints with at least one non-laminate segment. Moreover, it provides such a product comprising at least one laminate segment attached along area joints with at least one unitape segment. Additionally, it provides such a product comprising at least one laminate segment attached along area joints with at least one monofilament segment. Also, it provides such a product further comprising at least one rigid element.

In accordance with another preferred embodiment hereof, this invention provides a product wherein such at least one unidirectional tape is attached to such product. In accordance with a preferred embodiment hereof, the present system provides each and every novel feature, element, combination, step and/or method disclosed or suggested by this patent application.

### BRIEF GLOSSARY OF TERMS AND DEFINITIONS

Adhesive: A curable resin used to combine composite materials.
Anisotropic: Not isotropic; having mechanical and or physical properties which vary with direction at a point in the material.
Aerial Weight: The weight of fiber per unit area, this is often expressed as grams per square meter (g/m²).
Autoclave: A closed vessel for producing an environment of fluid pressure, with or without heat, to an enclosed object which is undergoing a chemical reaction or other operation.
B-stage: Generally defined herein as an intermediate stage in the reaction of some thermosetting resins. Materials are sometimes pre cure to this stage, called “prepregs”, to facilitate handling and processing prior to final cure.
C-Stage: Final stage in the reaction of certain resins in which the material is relatively insoluble and infusible.
Cure: To change the properties of a polymer resin irreversibly by chemical reaction. Cure may be accomplished by addition of curing (cross-linking) agents, with or without catalyst, and with or without heat.
Decitex (DTEX): Unit of the linear density of a continuous filament or yarn, equal to 1/10th of a tex or 9/10th of a denier
Dyneema™: Ultra-high-molecular-weight polyethylene fiber by DSM
Filament: The smallest unit of a fiber-containing material. Filaments usually are of long length and small diameter.
Polymer: An organic material composed of molecules of monomers linked together.
Prepreg: A ready-to-cure sheet or tape material. The resin is partially cured to a B-stage and supplied to a layup step prior to full cure.
Tow: An untwisted bundle of continuous filaments.
UHMWPE: Ultra-high-molecular-weight polyethylene. A type of polyolefin made up of extremely long chains of polyethylene. Trade names include Spectra® and Dyneema®
Unitape Uni-Directional tape (UD tape)—flexible reinforced tapes (also referred to as sheets) having uniformly-dense arrangements of reinforcing fibers in parallel alignment and impregnated with an adhesive resin. UD tape are typically B-staged and form the basic unit of most CT composite fabrics

### BRIEF DESCRIPTION OF THE DRAWINGS

FIG. 1 shows a perspective view, diagrammatically illustrating a flexible electronic fiber reinforced composite material, according to preferred embodiments of the present invention.

FIG. 2 shows a perspective view, diagrammatically illustrating a Single Layer composite material according to a preferred embodiment of the present invention.

FIG. 3 shows a perspective view, diagrammatically illustrating a Multilayer composite material according to a preferred embodiment of the present invention.

FIG. 4 shows a perspective view, diagrammatically illustrating a Layer by layer processed composite material according to a preferred embodiment of the present invention.

APPENDIX A contains further details and embodiments of the present invention.

### DETAILED DESCRIPTION OF THE BEST MODES AND PREFERRED EMBODIMENTS OF THE INVENTION

The present system comprises composite materials that incorporate high strength, tear-resistant substrates with conductive layers, or other layers, for electronic applications.

Preferred embodiments of the present system utilize unidirectional fiber-reinforced layers to form thin and smooth substrates that are suitable for etching or printing of electronic circuitry.

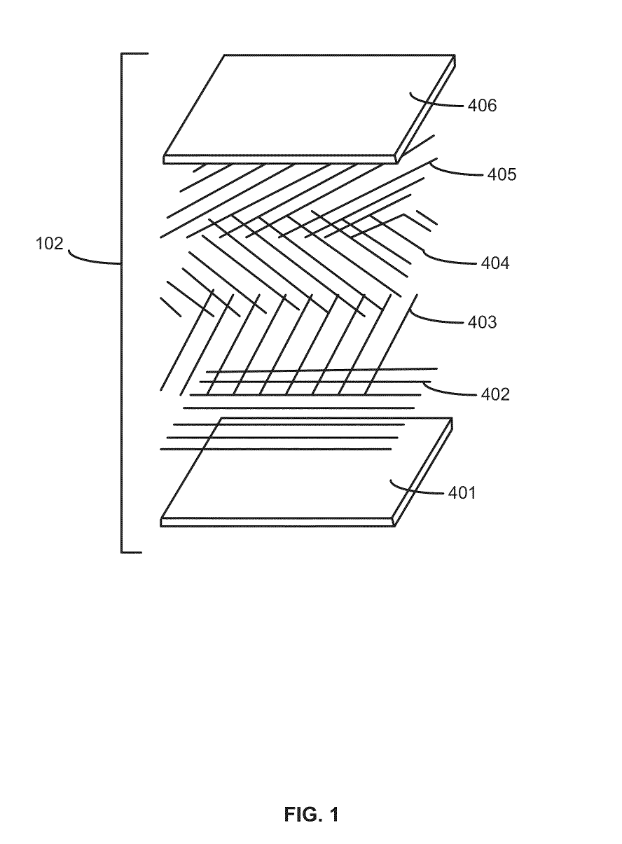

In reference to the drawings, FIG. 1 shows a perspective view, diagrammatically illustrating preferred flexible electronic fiber-reinforced composite material, hereinafter referred to as composite material 102, according to preferred embodiments of the present invention. The preferred composite material 102 is constructed by using one or multiple-layered portions and preferably described as at least three layered portions comprising at least one front surface layer 401, at least one back surface layer 406 and at least one reinforcing layer, preferably multiple reinforcing layers comprising reinforcing layer 402, reinforcing layer 403, reinforcing layer 404, and reinforcing layer 405, as shown.

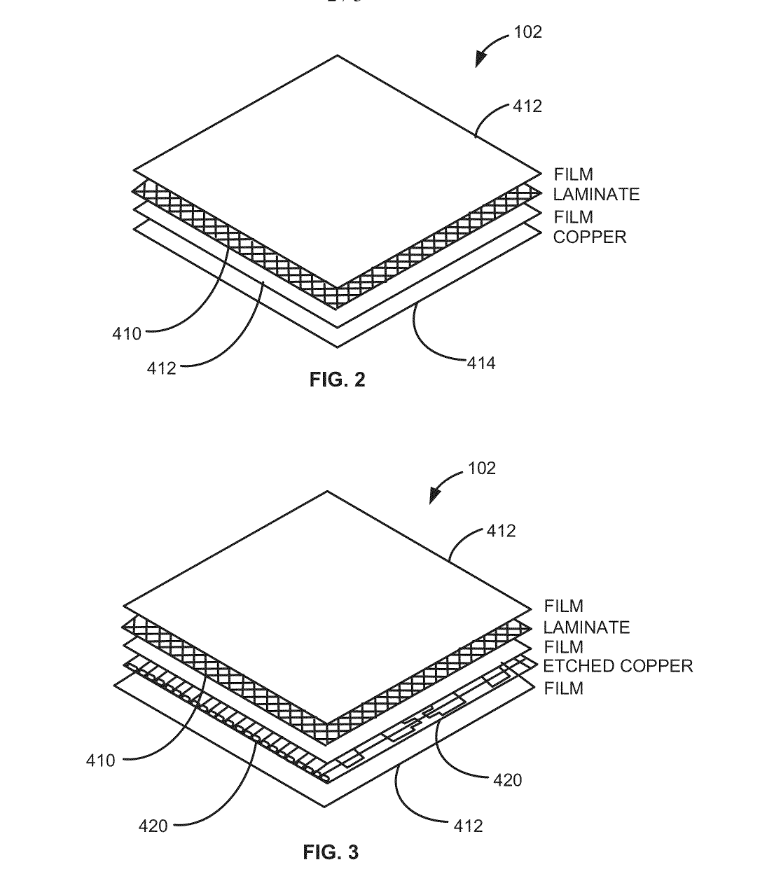

FIG. 2 shows a perspective view, diagrammatically illustrating another preferred embodiment of composite material 102 that further includes at least one conducting layer portion such as a continuous copper layer that may be etched by the user. In this alternate preferred embodiment, composite material 102 is preferably constructed by using one layer portion or multiple layer portions. The preferred layers preferably include a film layer 412, laminated layer portion 410, film layer 412, and copper layer 403. In this alternate preferred embodiment, the laminate layer portion 410 further include a laminate made up of at least a front surface layer 401, reinforcing layer 402, reinforcing layer 403, reinforcing layer 404, reinforcing layer 405, and a back surface layer 406.

FIG. 3 shows a perspective view, diagrammatically illustrating another preferred embodiment wherein circuits are pre-processed on film substrates and the user adds unitape-reinforcing layered portions (for reinforcing layer 402, reinforcing layer 403, reinforcing layer 404, reinforcing layer 405) and cover layer portions (front surface layer 401 and back surface layer 406). In the above-described alternate preferred embodiment, composite material 102 is preferably constructed by using one or multiple layered portions. The layered portions include a film layer 412, laminate layer portion 410, film layer 412, and etched-copper layer 420, and film layer 412. In this alternate preferred embodiment, the laminate layer portion 410 may include a front surface layer 401, reinforcing layer 402, reinforcing layer 403, reinforcing layer 404, reinforcing layer 405, and a back surface layer 406.

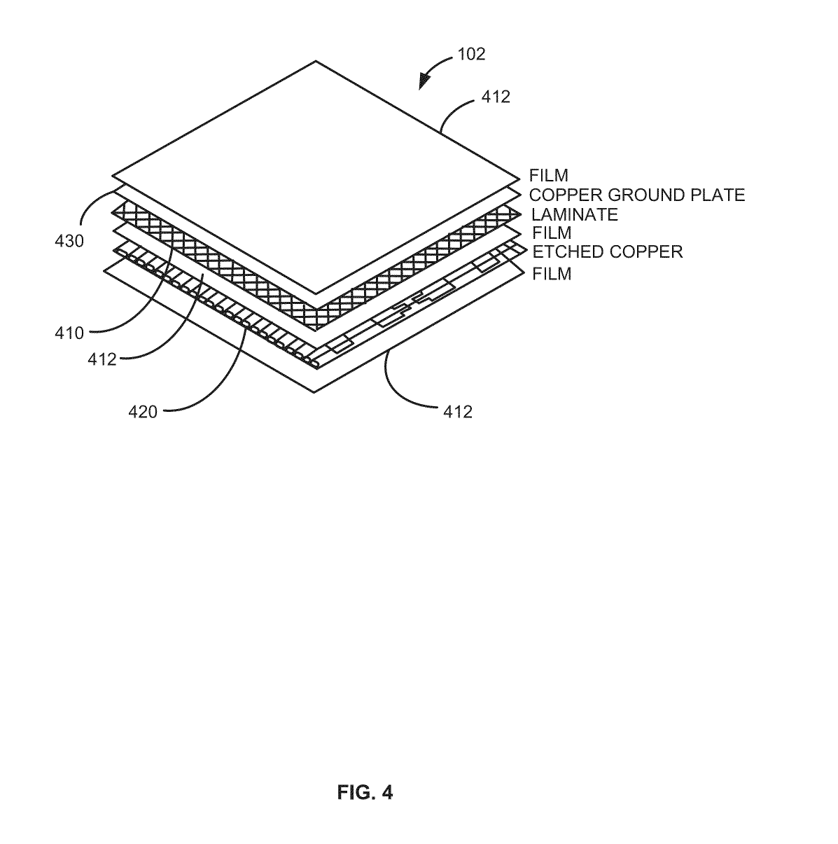

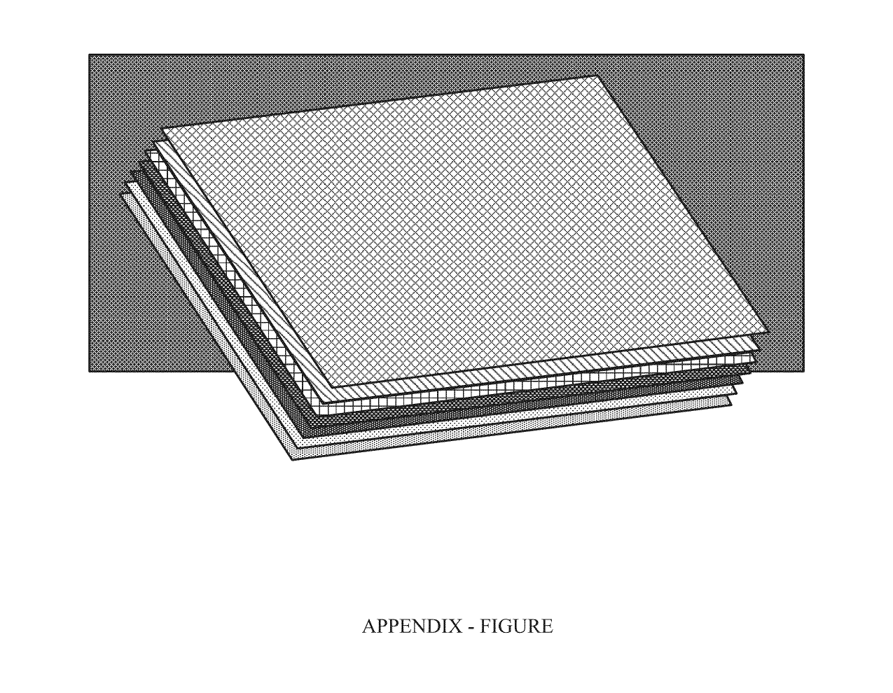

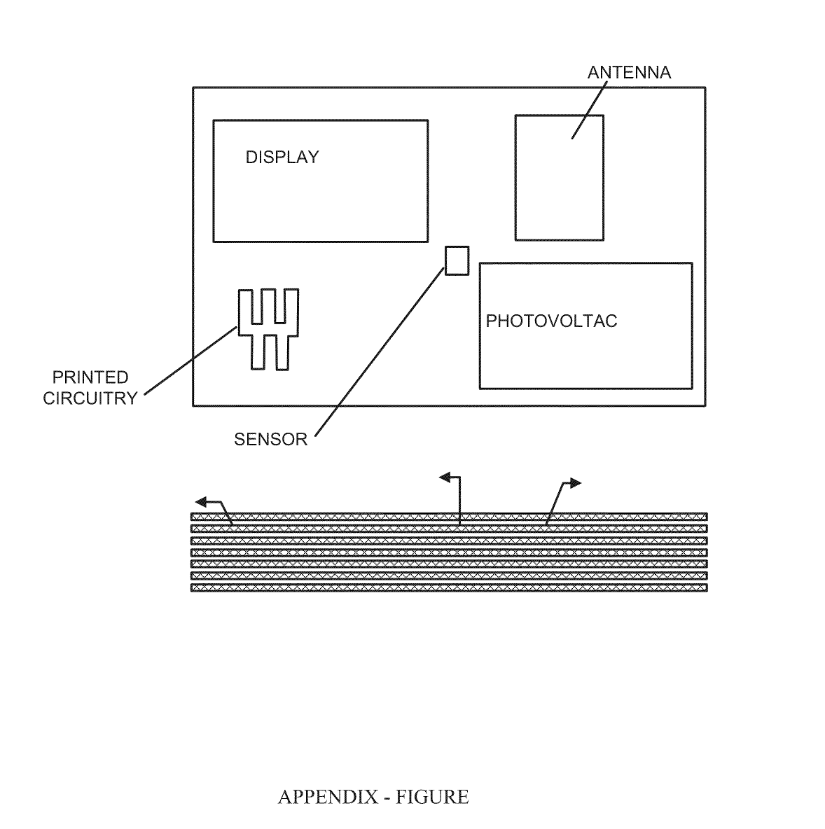

FIG. 4 shows a perspective view, diagrammatically illustrating another processed embodiments wherein circuits are added to single layer materials that return for one or more lamination steps to produce a multilayered flexible composite. In this alternate preferred embodiment, composite material 102 is constructed by using one or multiple layers, as shown. The layers preferably include a film layer 412, copper ground plate layer 430, laminate layer portion 410, film layer 412, and etched-copper layer 420, and film layer 412. In this alternate preferred embodiment the laminate layer portion 410 may include a front surface layer 401, reinforcing layer 402, reinforcing layer 403, reinforcing layer 404, reinforcing layer 405, and a back surface layer 406, as shown.

Composite material 102 is preferably between 12 g/m̂2 weight and 133 g/m̂2 in weight. Composite material 102 is preferably between 35 lb/in (−35,000 psi) and 515 lb/in (−73,000 psi) in strength. Composite material 102 preferably has approximately 3% elongation failure. Composite material 102 has a Modulas between −1200 lb/in (1,200,000 psi) and −17,000 lb/in (2,400,000 psi). Composite material 102 preferably is in the range of 0.001″ to 0.007″ in thickness. Composite material 102 preferably has fiber or filament stacking ranging from side by side to a center to center distance of approximately 9-fiber diameters.

Preferably, the front and back surface layers are coatings or films made from materials typical of electronic materials such as polyimide, PEN, Mylar, glass, or others. Alternate preferred films include metalized films. Other alternate preferred embodiments include interlayers of such films. Other alternate preferred embodiments omit such films.

Preferably, the reinforcing layer is constructed of one or more unitape sub-layers. A unitape is a fiber-reinforced layer having thinly spread parallel fibers preferably coated by adhesive. Preferably, each unitape sub-layer is directionally oriented, in a dedicated direction, to limit stretch and provide strength in such chosen direction, depending on the application. A two-direction unitape construction is preferred where the first unitape sub-layer has a 0° orientation and the second unitape sub-layer has a 90° orientation. In the same manner, preferred one-direction configurations, two-direction combinations, three-direction combinations, four-direction combinations, or other unitape combinations may be constructed. Preferred fiber types preferably suitable for reinforcing unitape sub-layers include Dyneema, Vectran, Aramid, polyester, nylon, or others. Depending on temperature requirements of secondary processing procedures it may be necessary to choose a high melt temperature fiber such as Vectran rather than Dyneema, which melts above 290° F. Dyneema has advantages for flexible electronics including high strength, high thermal conductively, and it highly flexible.

Compared to traditional woven fabrics of the same weight, the unitape reinforcing layers are significantly thinner, flatter, stronger, and more tear resistant. Oftentimes when a more durable circuit material is desired a thicker substrate film is chosen. For similar or even improved properties, a substrate that includes the thin fiber-reinforced unitape layers described in this invention can be utilized.

The material layers are preferably combined and cured together using pressure and temperature either by passing the stacked layers through a heated set of nips rolls, a heated press, a heated vacuum press, a heated belt press or by placing the stack of layers into a vacuum lamination tool and exposing the stack to heat. Preferred vacuum lamination tools are covered with a vacuum bag and preferably sealed to the lamination tool with a vacuum applied to provide pressure. Moreover, external pressure, such as provided by an autoclave, is used in the manufacture of the preferred embodiment, may be used to increase the pressure exerted on the layers. The combination of pressure and vacuum that the autoclave provides results in flat, thin, and well consolidated materials. Upon reading this specification, those with ordinary skill in the art will now appreciate that, under appropriate circumstances, considering such issues as design preference, user preferences, marketing preferences, cost, structural requirements, available materials, technological advances, etc., other lamination methods may suffice.

Preferred composite material(s) 102 include a metalized layer that may be masked and etched in subsequent steps to form electrical circuits. Preferred composite materials are also used as a substrate on which electrical circuits are printed. The preferred mechanical and thermal dimensional stability of applicant's composite material 102 allows for ease in processing. Preferably, the fiber type and content as well as choice of surface films creates low thermal expansion materials or materials with matched thermal expansion for a particular process or application.

The composite material(s) 102 described in the present disclosure have the following advantages over traditional monolithic circuit substrates: high strength-to-weight and strength-to-thickness, rip-stop, low or matched thermal expansion, tailored dielectric properties, and low heat transfer coefficients.

Additionally, the fiber reinforcement type, quantity, and orientation are preferably used to control and tailor heat flow because of the preference for heat to travel along the oriented polymer chains in engineering fibers.

Preferred applications for the composite material 102 described in this patent include, tightly assembles electronic packages, electrical connections where flexing is required during use, and electrical connections to replace heavier wire harnesses. Such product forms include flexible displays, flexible solar cells, and flexible antennas, etc.

Preferred system embodiments include:
Single Layer embodiment—a composite material 102 that includes one conducting layer such as a continuous copper layer that may be etched by the user.
Multilayer embodiments—Circuits are pre-processed on film substrates and the user adds the unitape reinforcing layers and cover layers.
Layer by layer processed embodiments—Circuits are added to single layer materials that return for one or more lamination steps to produce a multilayered flexible composite.

The composite material 102 preferably has the following properties:
strength
low stretch
strength can be engineered to match a required design
low CTE that closely matches that of many materials used in electronics, emerging technologies, and nano-materials
Thermal expansion can be isotropic for uniform, predictable, and strain matched thermal expansion. This allows for small, fine scale, circuits and electronic elements to be fabricated to precise tolerance in fine resolution and to maintain that space orientation relative to each other over wide temperature variations so circuit elements will maintain design performance tolerance in all directions and in plane.
High isotropic in-plane modulus provides low in-plane mechanical stretch due to mechanical loading, which allows the mechanical property analog of the CTE uniformity described above. The low stretch means that circuit elements do not change dimensions or the distance between features does not change due to load.

Bending strain on the circuit, device, or element is proportional to the distance that circuit, device, or element is from the neutral axis. The composite material 102 has an overall thinness and ability to locate the circuit, device, or element near the neutral axis so that strains and deformation due to curvature, distortion, bending, or crinkling are preferably minimized. Thus the service life of the circuit, device, or element on the composite material 102 is preferably increased. The above arrangement preferably enables the incorporation of high-resolution electronic devices, elements, circuits, antennas, RF devices, and LEDs.

The preferred structural features of the composite material 102 stabilize the features of the circuit so there is minimal fatigue and disbanding of elements due to repeated thermal cycles and load/vibration cycles. The CTE mismatch between many electronic elements causes large interfacial stress between the element and the substrate, which causes damage and fracturing of the element from the substrate leading to device failure.

The composite material 102 is preferably made from thin homogeneous, uniform unitapes that can produce smooth uniform laminates that are also thin, smooth and uniform in properties and thickness. The above arrangement is due to the uniform distribution of the monofilaments within the individual unitape layers. The unitapes can be oriented with ply angles such that the laminates can either have uniform properties in all directions, or the properties can be tailored to match a device, circuit, or other requirements.

The ability to produce a homogeneous, low stretch, low CTE composite material 102 with unidirectional layer orientation and a flat, smooth surface, allows for precise fabrication, deposition, printing, laser ablation, micromachining, etching, doping, vapor deposition, coating, 3D printing, application of multiple thin layers of various electronic materials and a wide range of other common processes that either require a flat or uniform material.

Preferred Applications of the present invention include:
Clothing with integrated antennas and sensors
Conformal applications for radars and antennas
EMI, RF and static protection
Structural membranes with integrated solar cells, wire traces embedded in the laminate, and on-board planar energy storage
Low cost integrated RFID system for package tracking
Flexible circuit boards
Ruggedize flexible displays
Flexible lighting

### ALTERNATE PREFERRED EMBODIMENTS

Preferably, conductive or non-conductive additives may be included in the adhesive of the unitape layers to alter the ESD (Electrostatic Discharge) or dielectric properties of the composite material. Preferably, fire retardant adhesives or polymers may be used, or fire retardants can be added to a flammable matrix or membrane to improve the flame resistance. Flame retardance or self extinguishing matrix resins or laminating or bonding adhesives such as Lubrizol 88111 can be used either by themselves or in combination with fire retardant additives. Examples of retardant additives include: DOW D.E.R. 593 Brominated Resin, DOW Corning 3 Fire Retardant Resin, and polyurethane resin with Antimony Trioxide (such as EMC-85/10A from PDM Neptec ltd.), although other fire retardant additives may also be suitable. Fire retardant additives that may be used to improve flame resistance include Fyrol FR-2, Fyrol HF-4, Fyrol PNX, Fyrol 6, and SaFRon 7700, although other additives may also be suitable. Fire retardancy and self extinguishing features can also be added to the fibers either by using fire retardant fibers such as Nomex or Kevlar, ceramic or metallic wire filaments, direct addition of fire retardant compounds to the fiber formulation during the fiber manufacturing process, or by coating the fibers with a sizing, polymer or adhesive incorporating fire retardant compounds listed above or others as appropriate. Any woven or scrim materials used in the laminate may be either be pretreated for fire retardancy by the supplier or coated and infused with fire retardant compounds during the manufacturing process.

Other preferred features include flexible composite electronic materials, such as:
Conductive polymer films
Ability to integrate thin flexible glass
Nanocoating of the fibers
Integrate nano materials into the film and matrix
Integrate EMI, RF, and static protection
Package to produce integration of the electronic device's functionality directly into the package
Layered construction analogous to many electrical circuit concepts so they are easily and efficiently integrated into the flexible format
Electrical Resistance
Thermal conductivity for thermal management and heat dissipation
Fiber optics
Energy storage using multilayered structures
In alternate preferred embodiments, filaments may be coated prior to processing into unitapes to add functionality such as thermal conductance or electrical capacitance as examples.

In an alternative embodiment, metal and dielectric layers may be included within the composite to add functionality such as reflection for solar cells, or capacitance for energy storage.

APPENDIX A, incorporated by reference hereby and made a part of this specification, contains further details and embodiments of the present invention.

### APPENDIX A

To further assist and clarify in enabling of the present invention to those with ordinary skill in this art, the following additional examples of preferred embodiments are provided.

The following figure shows a perspective view, diagrammatically illustrating a multilayered composite material wherein circuits are added to multiple layers of the composite materials that return for one or more lamination steps to produce multilayered flexible composite. In this alternate preferred embodiment, composite material is constructed by using one or multiple layers, as shown. The layers preferably include a film layer, circuitry layer, laminate layer portion, etched copper layer, with additional layers. In this alternate preferred embodiment the laminate layer portion may include a front surface layer, reinforcing layer, reinforcing layer, reinforcing layer, reinforcing layer, and a back surface layer, as shown discussed previously.

The following figures shows top view of the circuitry layer and an edge schematic view illustrating a multilayered composite material with circuitry shown in the previous figure, according to a preferred embodiment of the present invention.

Although applicant has described applicant's preferred embodiments of this invention, it will be understood that the broadest scope of this invention includes modifications such as diverse shapes, sizes, and materials. Such scope is limited only by the below claims as read in connection with the above specification. Further, many other advantages of applicant's invention will be apparent to those skilled in the art from the above descriptions and the below claims.

1. A composite material for electronic applications comprising:
a. at least one conductive layer; and
b. at least one laminate layer bonded to said conductive layer and comprising at least one unidirectional tape layer comprising monofilaments coated in an adhesive, all of said monofilaments lying in a predetermined direction within said tape,
wherein said monofilaments have diameters less than 20 microns, and wherein spacing between individual monofilaments within an adjoining strengthening group of monofilaments is within a gap distance in the range between non-abutting monofilaments up to nine times the monofilament major diameter.

2. The composite material of claim 1, wherein said laminate layer comprises first, second, third and fourth unidirectional tape layers sequentially stacked, bonded together and directionally oriented such that the monofilament directions within said layers are at 0°, 90°, 45°, and −45° relative to one another.

3. The composite material of claim 1, wherein said conductive layer comprises a copper layer capable of being etched, an etched-copper layer, a copper ground plate layer, or an electronic circuit pre-processed on a film substrate.

4. The composite material of claim 1, wherein said adhesive comprises a conductive or non-conductive additive capable of altering the electrostatic discharge or dielectric properties of said composite material.

5. The composite material of claim 1, wherein said laminate layer is disposed between a front surface layer and a back surface layer such that either of said front or back surface layers is bonded to said conductive layer.

6. The composite material of claim 5, wherein said front and back surface layers comprise coatings or films comprising polyamide, PEN, Mylar or glass.

7. The composite material of claim 5, wherein at least one of the front surface layer and back surface layer comprises a metallized film or a conductive polymer film.

8. The composite material of claim 5, further comprising a film layer bonded to said conductive layer on a side of said conductive layer not bonded to either of said front or back surface layers.

9. The composite material of claim 1, further comprising: (a) a copper ground plate layer bonded to said laminate layer; and (b) first, second and third film layers, wherein said first film layer is bonded to said copper ground plate layer, said second film layer is bonded to said laminate layer, and said third film layer is bonded to said conductive layer, and wherein said layers are disposed in consecutive order: first film layer, copper ground plate layer, laminate layer, second film layer, conductive layer, and third film layer.

10. The composite material of claim 9, wherein said conductive layer comprises a copper layer capable of being etched, an etched-copper layer, a second copper ground plate layer, or an electronic circuit pre-processed on a film substrate.

11. The composite material of claim 9, wherein said laminate layer comprises first, second, third and fourth unidirectional tape layers sequentially stacked, bonded together and directionally oriented such that the monofilament directions within said layers are at 0°, 90°, 45°, and −45° relative to one another.

12. A method of manufacturing an electronic composite material, said method comprising:
(a) providing a laminate layer comprising at least one unidirectional tape layer comprising parallel monofilaments coated in an adhesive, all of said monofilaments thinly spread in a predetermined direction; and
(b) printing, depositing, or bonding a conductive layer onto said laminate layer.

13. The method of claim 12, wherein said laminate layer comprises a directionally oriented stack of four unidirectional tape layers such that the monofilament directions within said unidirectional tape layers are at 0°, 90°, 45°, and −45° relative to one another.

14. The method of claim 13, further comprising a step of curing said stack to form said laminate layer.

15. The method of claim 14, wherein said curing comprises passing said stack through a heated set of nip rollers, a heated press, a heated vacuum press, or a heated belt press, or placing said stack into a vacuum lamination tool and subjecting said stack to heat.

16. The method of claim 15, wherein said curing includes use of an autoclave.

17. The method of claim 12, wherein said conductive layer comprises a copper layer capable of being etched, an etched-copper layer, a copper ground plate layer, or an electronic circuit pre-processed on a film substrate.

18. The method of claim 17, wherein said conductive layer is a copper layer capable of being etched, and said method further comprises a step of etching said copper layer into a circuit diagram after said step of printing, depositing or bonding said conductive layer onto said laminate layer.

19. The method of claim 12, further comprising a step of bonding at least one cover layer onto said electronic composite material.

20. The method of claim 12, further comprising a step of adding at least one film layer.
